(19) United States
(12) Patent Application Publication
(10) Pub. No.: US 2025/0060232 A1
(43) Pub. Date: Feb. 20, 2025

(54) BEHAVIORAL CHANGE DETECTION OF ROOM SENSORS MEASUREMENTS FOR DC EFFICIENCY IMPROVEMENT

(71) Applicant: HITACHI, Ltd., Tokyo (JP)

(72) Inventor: Jana BACKHUS, San Jose, CA (US)

(21) Appl. No.: 18/233,595

(22) Filed: Aug. 14, 2023

(51) Int. Cl. G01D 18/00; H05K 7/20

(52) U.S. Cl. CPC G01D 18/00; H05K 7/20836; G01D 2218/10

(57) ABSTRACT

Aspects of the present disclosure involve systems and methods, which can include executing an incremental Principal Component Analysis (PCA) modeler to build a PCA model for sensor measurements associated with one or more cooling devices of a location to be monitored; detecting changes at each time step based on a change in a number of principal components or for when a reconstruction error exceeds a threshold; and evaluating and observing changes to generate feedback regarding the one or more cooling devices.

### BACKGROUND

### Field

The present disclosure is generally related to data centers, and more specifically, to behavioral change detection of room sensor measurements in data centers.

### Related Art

Data centers (DC) are heavy users of electricity and there is an ever-continuous effort to be more energy efficient. One important aspect of energy efficiency is the reduction of the amount of cooling power that is used for a certain amount of Information Technology (IT) equipment power. State-of-the-art metrics such as power usage effectiveness (PUE) or Data Center infrastructure Efficiency (DciE) can be used to express energy efficiency of a DC infrastructure. However, these metrics do not account for the actual operational state of the DC server rooms. For example, environmental sensors that measure indoor temperature and indoor humidity of a server room can change over time without any changes in the overall energy efficiency (measured by metrics such as PUE). Monitoring the behavioral changes of sensor measurements in a spatial entity such as a server room can help to detect operational states that could be improved.

In related art implementations, there can be a building management system that includes connected equipment and a predictive diagnostic system. The predictive diagnostic system includes a PCA modeler that constructs PCA models for a plurality of operating states from the monitored variables of the connected equipment. An additional fault predictor is configured to determine a proximity of a new sample of the monitored variable to one or more of the operating states, where each operating state is modeled by a different PCA model.

In the related art, there are also implementations for incremental PCA modeling for server room temperature sensor anomaly detection in the context of DCs. This is however limited to the use of incremental PCA to detect anomalies in the case of increasing or decreasing number of principal components.

### SUMMARY

There is a need for a behavioral change detection method for DC server room sensors that can detect changes in the behavioral relationship between sensor measurements. The detected changes then need to be evaluated on their importance, such as whether there are on-going changes in the room conditions. If the change can be considered important, then recommendations can be made about changing the cooling device operations in various circumstances, such as when the indoor temperature is decreasing more than necessary.

The related art implementations do not involve a broader solution where additional ‘reconstruction error’ and several additional change check steps are used to only report important behavioral changes.

Continuous improvement of DCs energy efficiency is important in the scope of on-going sustainability efforts. It is straightforward to observe DC-based efficiency metrics (e.g., PUE,) and recommend possible improvements when the PUE has changed for the worse. However, sometimes the operational state of the server room (e.g., the indoor temperature or humidity) can give insights about additional situations that cannot be observed by efficiency metrics alone.

FIG. 1 illustrates an example of an operational state of a real-world DC server room, in accordance with an example implementation. Here, the PUE metric is stable over the observed time period, but there is a decrease in the indoor temperature (in_temp in FIG. 1). This decrease in indoor temperature is caused by an operational change in the cooling power (cool_pwr in FIG. 1), where the total cooling power of the room stays stable, but the standard deviation changes drastically. Therefore, detecting changes in the operational state of a server room (here: indoor temperature) can potentially improve the overall operational state when appropriate feedback is given to a DC operator. In the current example, the average indoor temperature of all sensors in the server room is 2° C. below the goal temperature after the change date. It is possible to improve the efficiency of this server room by decreasing the amount of cooling power, since obviously after the operational change less cooling power is necessary to operate the server room at an indoor temperature that is below the goal threshold.

The example of FIG. 1 shows that it is important to not just detect changes in the behavioral relationship of sensor measurements, but also to observe and reevaluate them over a longer time to provide feedback to DC operators for efficiency improvements.

In related art implementations, the PCA is used to divide the data according to operation states and calculate the proximity of newly arriving samples to those states. This is different from the example implementations described herein, because the goal of leveraging PCA is to detect behavioral changes in the data not to handle different operating states for later fault detection. In addition, PCA models are updated incrementally based on a spatial identifier and adopted to the new state while forgetting about the previous behavioral state over time.

Aspects of the present disclosure can involve a method, which can include executing an incremental Principal Component Analysis (PCA) modeler to build a PCA model for sensor measurements associated with one or more cooling devices of a location to be monitored; detecting changes at each time step based on a change in a number of principal components or for when a reconstruction error exceeds a threshold; and evaluating and observing changes to generate feedback regarding the one or more cooling devices.

Aspects of the present disclosure can involve a computer program, which can include instructions involving executing an incremental Principal Component Analysis (PCA) modeler to build a PCA model for sensor measurements associated with one or more cooling devices of a location to be monitored; detecting changes at each time step based on a change in a number of principal components or for when a reconstruction error exceeds a threshold; and evaluating and observing changes to generate feedback regarding the one or more cooling devices. The computer program and instructions can be stored on a non-transitory computer readable medium and executed by one or more processors.

Aspects of the present disclosure can involve a system, which can include means for executing an incremental Principal Component Analysis (PCA) modeler to build a PCA model for sensor measurements associated with one or more cooling devices of a location to be monitored; means for detecting changes at each time step based on a change in a number of principal components or for when a reconstruction error exceeds a threshold; and means for evaluating and observing changes to generate feedback regarding the one or more cooling devices.

Aspects of the present disclosure can involve an apparatus, which can include a processor, configured to execute an incremental Principal Component Analysis (PCA) modeler to build a PCA model for sensor measurements associated with one or more cooling devices of a location to be monitored; detect changes at each time step based on a change in a number of principal components or for when a reconstruction error exceeds a threshold; and evaluate and observing changes to generate feedback regarding the one or more cooling devices.

### BRIEF DESCRIPTION OF DRAWINGS

FIG. 1 illustrates an example of an operational state in a DC server room, in accordance with an example implementation.

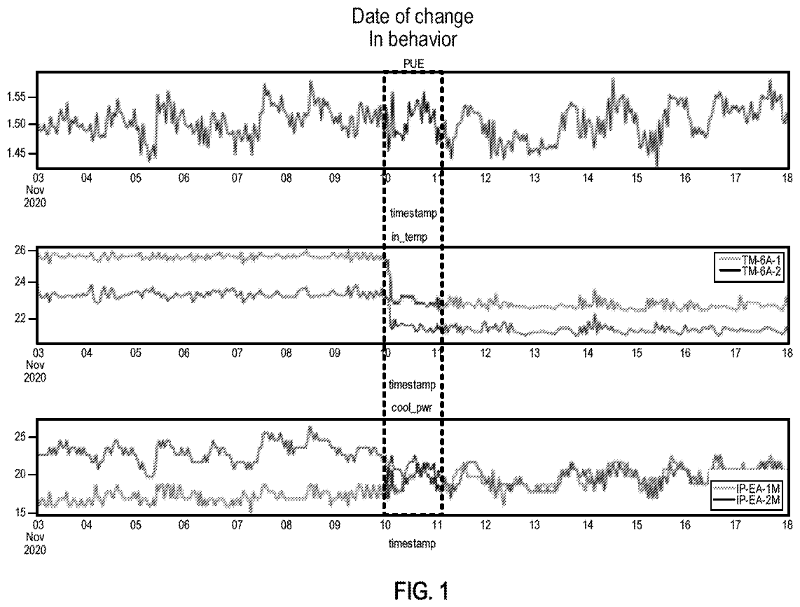

FIG. 2 illustrates the overall system, in accordance with an example implementation.

FIG. 3 illustrates the incremental PCA modeler, in accordance with an example implementation.

FIG. 4 illustrates an example of the change detector 220, in accordance with an example implementation.

FIG. 5 illustrates an example of the change information database, in accordance with an example implementation.

FIG. 6 illustrates the overall flow of the change evaluator, in accordance with an example implementation.

FIG. 7 illustrates an example flow for the change calculator, in accordance with an example implementation.

FIG. 8 illustrates some example score metric calculations for the change calculator, in accordance with an example implementation.

FIG. 9 illustrates the example flow diagram for the feedback creator, in accordance with an example implementation.

FIG. 10 illustrates an example of a feedback condition table that is used to calculate the change in the before to after periods of the change date and give feedback accordingly, in accordance with an example implementation.

FIG. 11 illustrates an example of output on a display that can be leveraged by DC operators to observe detected changes and related feedback (if available), in accordance with an example implementation.

FIG. 12 illustrates how the sensor-based change detection can help to localize changes in the operational state of the DC, in accordance with an example implementation.

FIG. 13 illustrates a real-world example of a change that only affects one of the sensors of the server room, in accordance with an example implementation.

FIG. 14 illustrates an example of a short-term outlier, where the temperature is temporarily strongly decreasing but then returns to a normal state, in accordance with an example implementation.

FIG. 15 illustrates an example computing environment with an example computer device suitable for use in some example implementations.

### DETAILED DESCRIPTION

The following detailed description provides details of the figures and example implementations of the present application. Reference numerals and descriptions of redundant elements between figures are omitted for clarity. Terms used throughout the description are provided as examples and are not intended to be limiting. For example, the use of the term “automatic” may involve fully automatic or semi-automatic implementations involving user or administrator control over certain aspects of the implementation, depending on the desired implementation of one of ordinary skill in the art practicing implementations of the present application. Selection can be conducted by a user through a user interface or other input means or can be implemented through a desired algorithm. Example implementations as described herein can be utilized either singularly or in combination and the functionality of the example implementations can be implemented through any means according to the desired implementations.

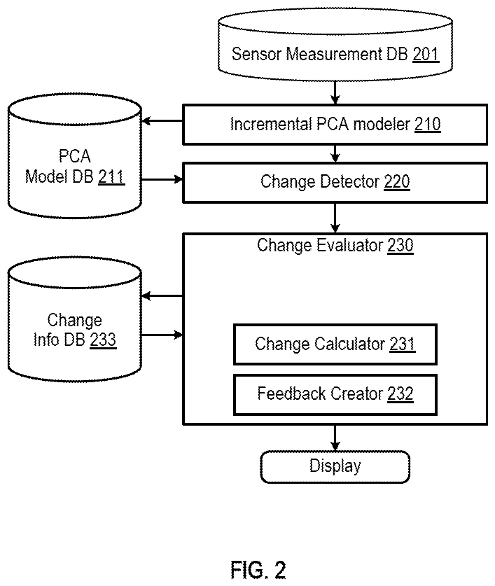

FIG. 2 illustrates the overall system, in accordance with an example implementation. The system can involve three main elements as follows.

Incremental PCA modeler 210 is configured to build a PCA model for sensor measurements processed from sensor measurement database 201 as received from each DC server room or other spatial entity, whereupon all of the PCA models are managed in a PCA model database 211 for use by the change detector 220. Using an incremental PCA makes fine-grained update and change analysis of sensor measurements possible. The PCA models learn the behavioral relationship between the observed sensor measurements for the DC server room or other spatial entity.

Change Detector 220 detects changes at each time step based on whether any of the following two conditions is true: 1) the number of principal components increased (or decreased), 2) the reconstruction error is exceeding a threshold. The two conditions for the detectors are used so that the behavioral changes of the sensor measurement relationships are found as instabilities in the incremental PCA model that is updated at each time step. The two conditions are used because the algorithm needs time to adjust after a change occurs in the number of principal components, and new changes might also not be detected if there is no second reconstruction error-based change detection available. Further, reconstruction error-based change detection can be used when the number of sensor measurements are small (e.g., only two measurements are available, and the maximum number of principal components is one).

Change Evaluator 230 observes and reevaluates changes via a change calculator 231, and has a feedback creator 232 to create feedback after evaluating the change. The change evaluator 230 can identify unnecessary changes detected by instabilities in the PCA algorithm, identify short-term outliers that are not of interest, reconfirm change importance over a longer time period and localize changes based on sensor change scores. The changes detected can be stored in a change information database 233.

Change calculator 231 can eliminate unimportant changes by evaluating change in multiple iterations. For example, a short-term check can check if detected change is big enough to be considered. A mid-term check can check if detected change is still there and it was not just an outlier. A long-term check can check if the change is affecting the performance even after a longer time period has passed.

Feedback creator 232 provides feedback regarding performance impacts (e.g., PUE increasing and temperature decreasing (+too low); temperature largely increased (too high)), and gives recommendations on further performance improvements (e.g., indoor temperature is very low and could be higher).

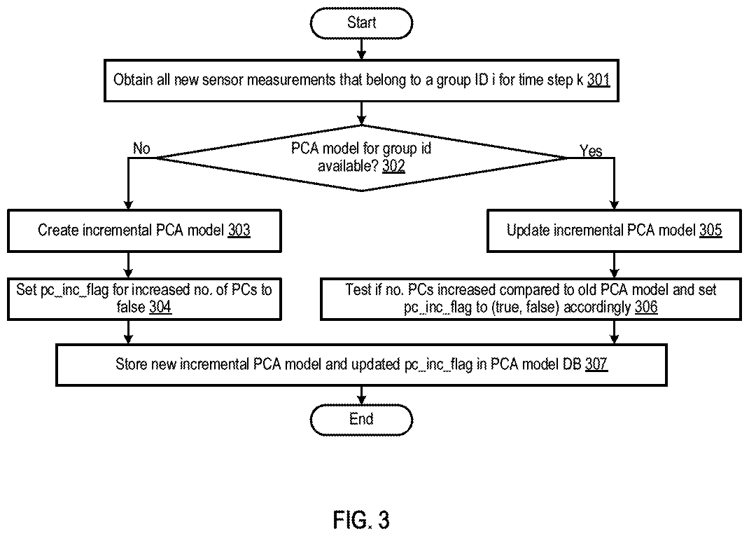

FIG. 3 illustrates the incremental PCA modeler 210, in accordance with an example implementation. For each group identifier i managed by the system, the incremental PCA modeler 210 executes the following process. At first at 301, the incremental PCA modeler obtains all new sensor measurements that belong to a group identifier i for time step k. At 302, a determination is made as to whether a PCA model for that group identifier is available. If so (yes) then the flow proceeds to 305, otherwise (no), an incremental PCA model is generated for the group identifier at 303. At 304, a flag is associated with the newly generated PCA model to indicate that the components have not increased over time, as the model was just created.

At 305, the incremental PCA model is updated with the new sensor measurements to form a new incremental PCA model. At 306, a determination is made as to whether the number of principal components has increased from the previous incremental PCA model in comparison to the new incremental PCA model. The flag associated with the incremental PCA model is set to true or false based on the result.

At 307, the new incremental PCA model and the associated flag regarding any increase in components is saved in the PCA model database 211.

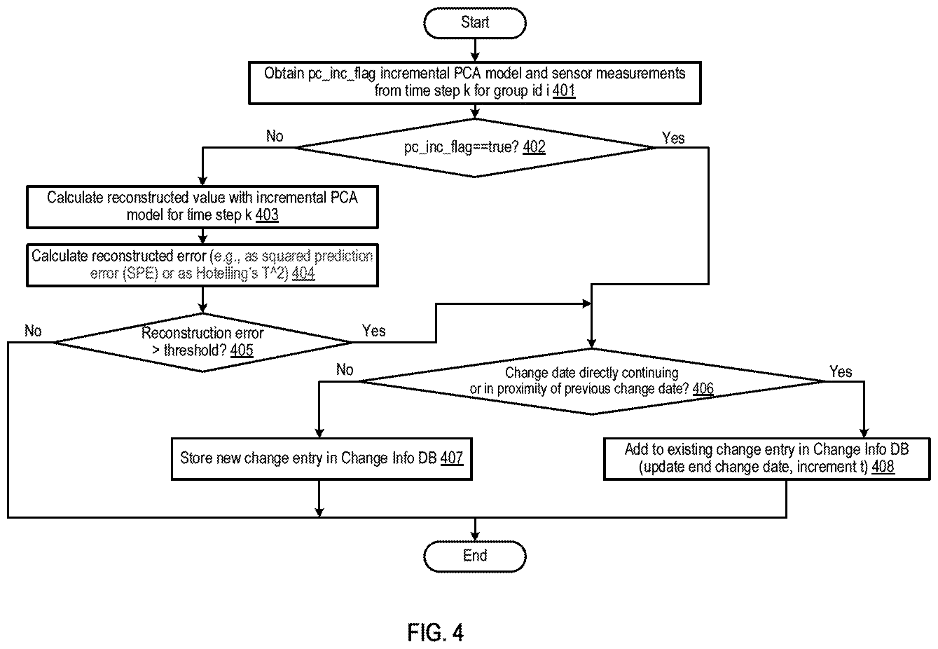

FIG. 4 illustrates an example of the change detector 220, in accordance with an example implementation. For each group identifier i, the change detector 220 executes the following flow.

At 401, the change detector obtains the incremental PCA model associated with the group identifier i, along with the associated flag regarding any increase in components and sensor measurements from time step k. At 402, a determination is made as to whether the flag indicates that the number of components has increased (pc_inc_flag=true). If so (yes), then the flow proceeds to 406, otherwise (no) the flow proceeds to 403.

At 403, the flow calculates the reconstructed value with incremental PCA model for time step k. At 404, the flow calculates the reconstruction error, which can be conducted with any technique in the art, such as but not limited to squared prediction error (SPE) or as Hotelling's T\hat{ }2. At 405, a determination is made as to whether the reconstruction error is greater than a threshold. If so (yes), then the flow proceeds to 406, otherwise (no) the flow ends.

At 406, a determination is made as to whether the change date directly continues or is in close proximity from the previous change date. Close proximity can be determined as a fluctuation threshold (e.g., some fluctuations occurred but the last change was detected two hours ago, and the change was detected again which was not identified as a change one hour ago). If not (no), then the flow proceeds to 407 to store the new change entry into the change information database 233, otherwise (yes), the flow proceeds to 408 to look up the corresponding change entry in the change information database 233 and add to the existing entry. When adding to the existing change entry, the end change date is updated with the new change date, and the timer t is incremented.

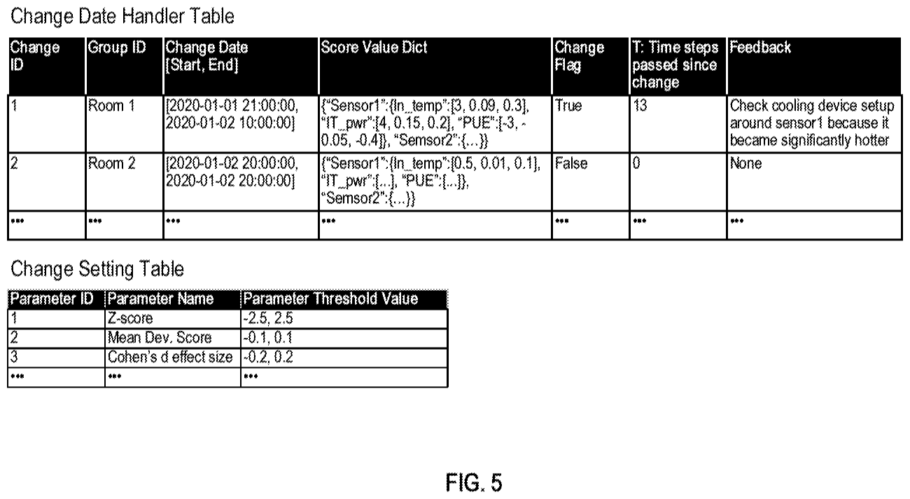

FIG. 5 illustrates an example of the change information database, in accordance with an example implementation. Specifically, FIG. 5 illustrates example tables from the change information database that handles information about the detected changes. The tables can include the change date handler table and the change setting table.

The change date handler table can involve a change identifier, group identifier, the change date (start and end), the score value dictionary, the change flag, the time steps passed since the last change, the feedback, and so on. The change setting table can involve the parameter identifier, the parameter name, and the parameter threshold value.

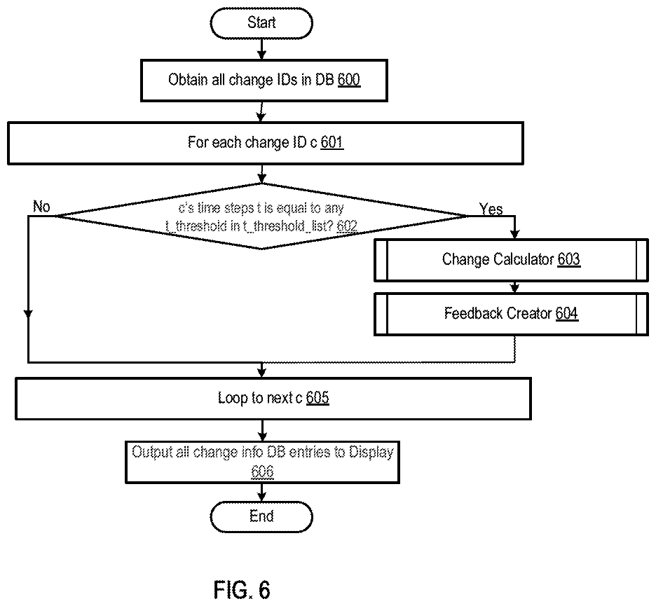

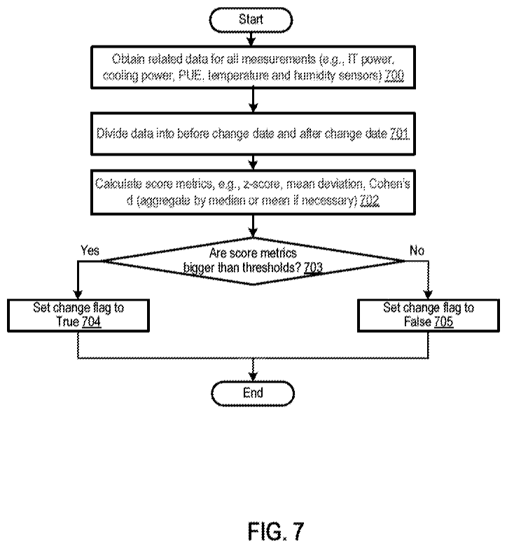

FIG. 6 illustrates the overall flow of the change evaluator 230, in accordance with an example implementation. The change evaluator 230 is executed for each processing time step. At 600, all of the change identifier entries are obtained from the change information database 234. At 601, each change ID c is then processed. At 602, a determination is made as to whether the time steps t have passed to meet the t_threshold in the t_threshold list. If not (no), then the flow proceeds to 605 to loop to the next change ID c, otherwise (yes) the flow proceeds to 603 to execute the change calculator 231. At 604, the feedback creator 232 is then executed, whereupon the loop to the next change ID c is conducted at 605 to repeat from 601. At 606, all of the change information database entries are then output for display. Further details are provided with respect to FIGS. 7-11.

FIG. 7 illustrates an example flow for the change calculator 231, in accordance with an example implementation. Possible ways of calculating the change between before to after periods of the change date include comparing the averages for each metric or employing methods of causal inference. The flow is executed for each change identifier provided. At 700, the flow obtains related data for all measurements (e.g., IT power, cooling power, PUE, temperature, humidity sensor measurements, etc.) At 701, the obtained related data is divided into before the change date and after the change date.

At 702, the flow calculates score metrics, such as the z-score, mean deviation, and so on. Since sensor measurements are time series, the related data is selected accordingly. For example, if weekly seasonality is observed with differences between weekdays and weekends, the corresponding related data is selected to adjust for seasonality. At 703, a determination is made as to whether the score metrics are bigger than the thresholds. If so (yes), then the associated change flag is set to true at 704, otherwise (no) the change flag is set to false at 705.

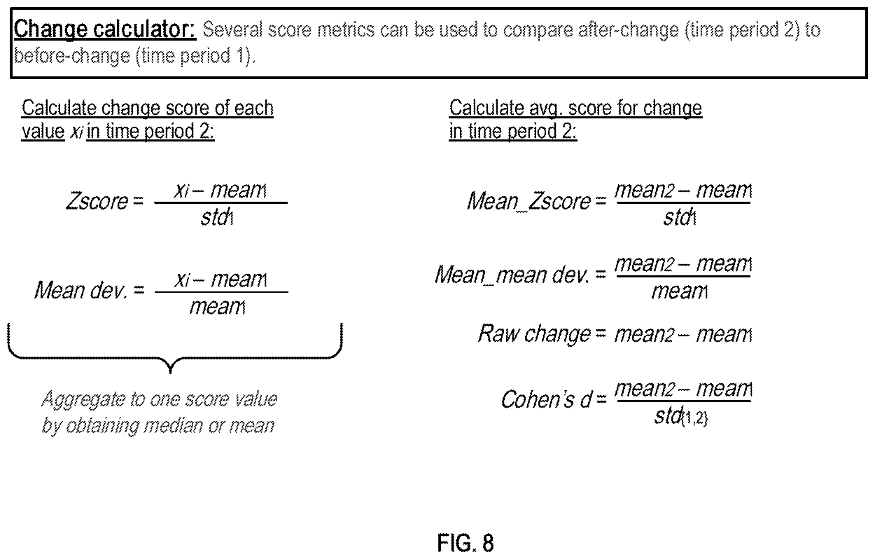

FIG. 8 illustrates some example score metric calculations for the change calculator, in accordance with an example implementation. The metrics illustrated in FIG. 8 can be used to evaluate short-term, mid-term, or long-term importance of a detected change.

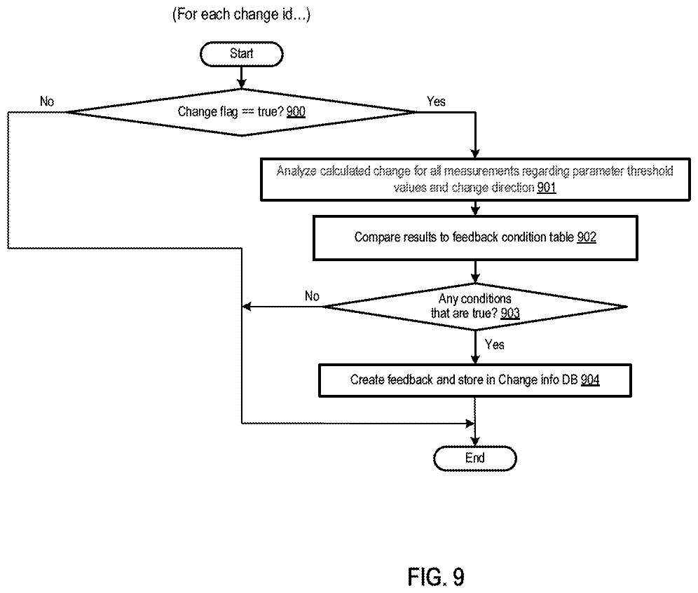

FIG. 9 illustrates the example flow diagram for the feedback creator, in accordance with an example implementation. The flow is executed for each change ID found in the change information database 234. At 900, a determination is made as to whether the change flag is set to true. If so (yes), then the flow proceeds to 901 to analyze the calculated change for all measurements regarding parameter threshold values and change direction. At 902, the flow compares results to the feedback condition table. At 903, a check is made to determine if any conditions are true. If so, (yes), then the flow proceeds to 904, to create feedback and store in the change info DB.

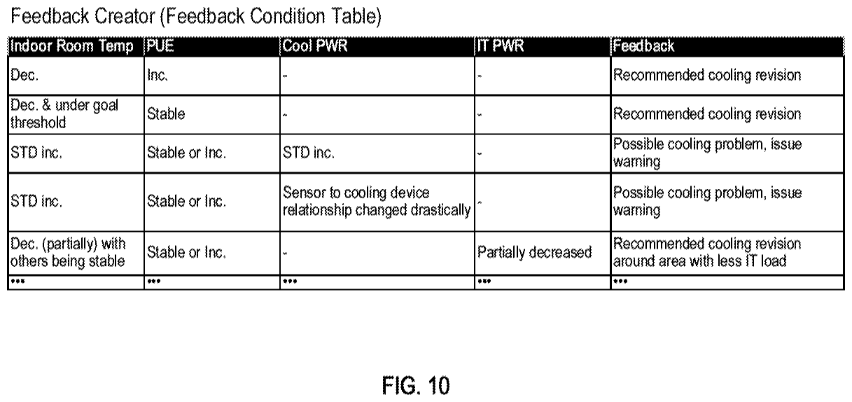

FIG. 10 illustrates an example of a feedback condition table that is used to calculate the change in the before to after periods of the change date and give feedback accordingly, in accordance with an example implementation. This step does not only include the data center (DC) server room sensor measurements, but can also include other measurements as for example PUE, cooling power usage, IT power usage, and so on in accordance with the desired implementation.

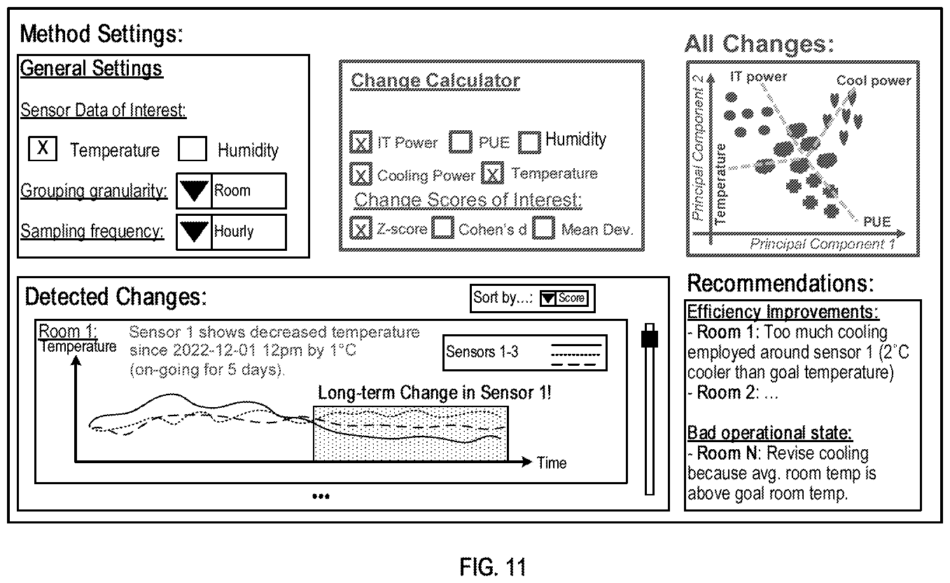

FIG. 11 illustrates an example of output on a display that can be leveraged by DC operators to observe detected changes and related feedback (if available), in accordance with an example implementation. Examples of functions in the display interface can involve general settings, change calculator, detected changes, all changes, and recommendations.

General settings can include a selection of the sensor data of interest for the change detector (e.g., temperature, humidity), the grouping granularity (e.g., by room, by server group, etc.), and the sampling frequency (e.g., hourly, daily, etc.). Change calculator can involve selection for measurements of interest, such as IT Power, PUE, Humidity, Cooling Power, Temperature, and so on, as well as change scores of interest (e.g., Z-score, Cohen's d, mean deviation etc.). Detected Changes can indicate changes from the change detector in graphical form, including insights regarding any long-term changes that were detected. All changes can display any changes in the underlying principal components in graphical form over several or all group ids. Recommendations can display any recommendations to mitigate the underlying detected changes, such as efficiency improvements or bad operational states that need to be fixed, and so on.

By observing the changes in the behavioral conditions between sensor measurements, it is possible to observe sudden changes, for example, for the temperature or humidity in a DC server room. This can give more detailed insights about how changing cooling behavior or server usage patterns affect the operational state of the room. Further, example implementations can identify additional changes in the operational state that are not visible from energy consumption data (IT devices, cooling) alone.

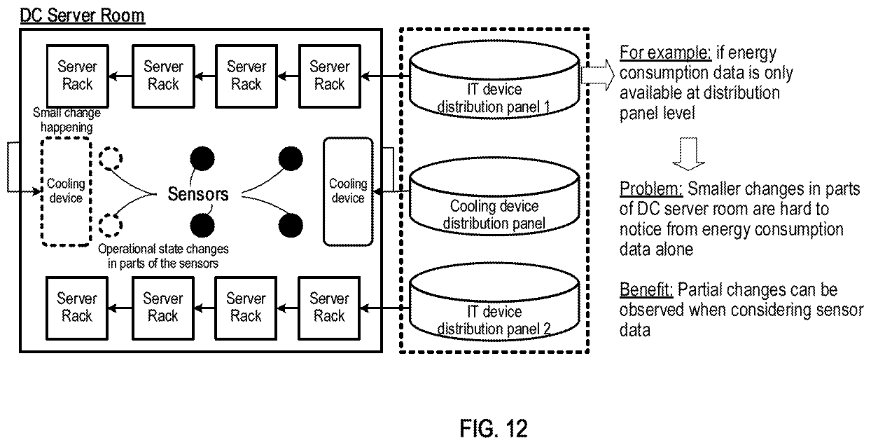

FIG. 12 illustrates how the sensor-based change detection can help to localize changes in the operational state of the DC, in accordance with an example implementation. In a DC where detailed power consumption information is not available and power consumption is only measured at a high level like a distribution panel, sensors can help to localize changes, because the sensors are representing the operational state of a certain area of a server room.

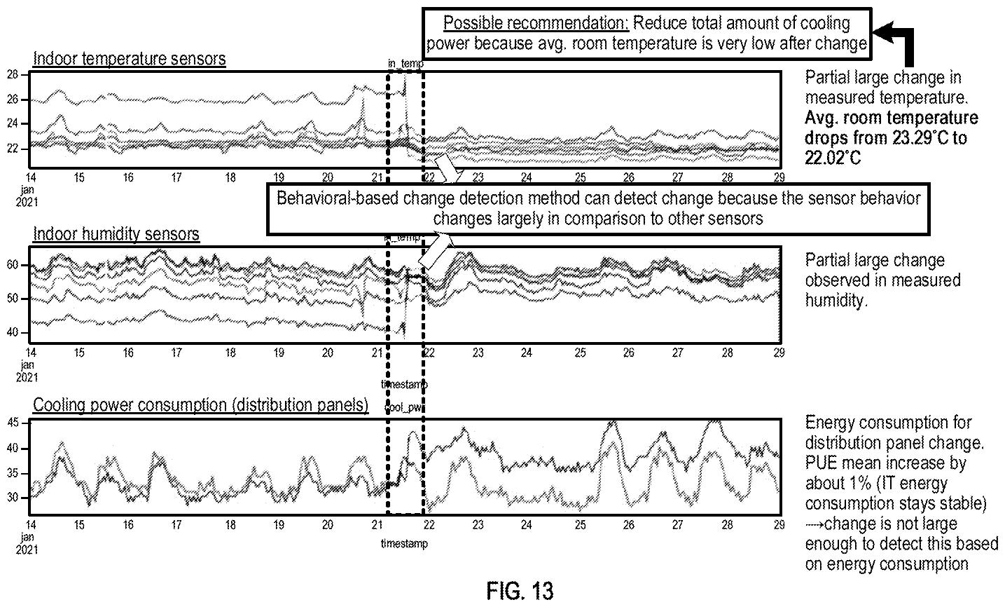

FIG. 13 illustrates a real-world example of a change that only affects one sensor of the server room, in accordance with an example implementation. In comparison, cooling power consumption can only be observed on the level of the distribution panel and it would be harder to locate the exact location of the change.

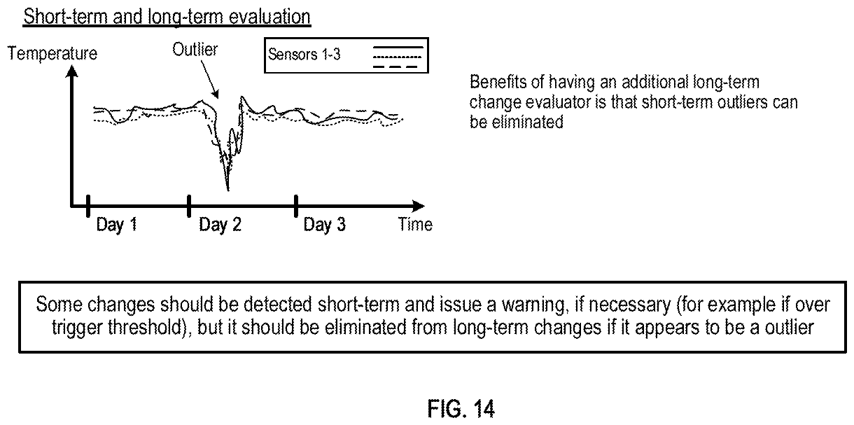

FIG. 14 illustrates an example of a short-term outlier, where the temperature is temporarily strongly decreasing but then returns to a normal state, in accordance with an example implementation. If the change in state is only temporary, it is good to issue a warning to the DC operator but also to inform about return to normal state and reevaluation of the importance of the change Depending on the desired implementation, some changes can be detected short-term and a warning is issued, if necessary (for example if over a trigger threshold), but it should be eliminated from long-term changes if it appears to be an outlier.

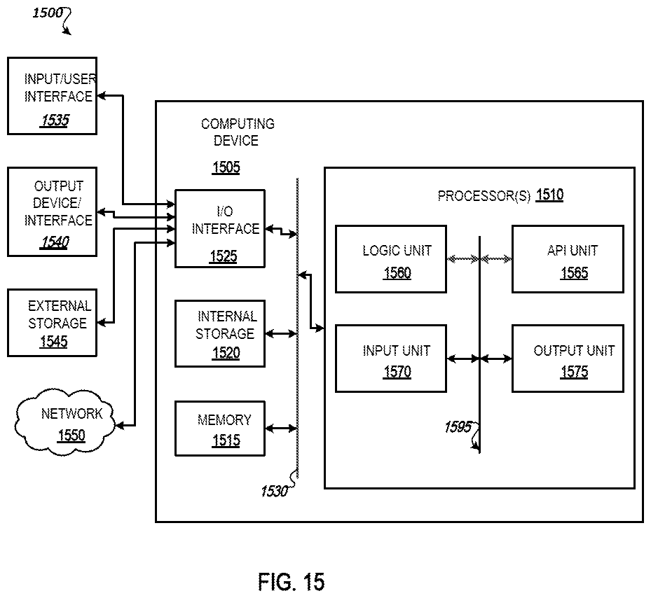

FIG. 15 illustrates an example computing environment with an example computer device suitable for use in some example implementations, such as a management server or management computer configured to execute the functions as described in FIG. 2. Computer device 1505 in computing environment 1500 can include one or more processing units, cores, or processors 1510, memory 1515 (e.g., RAM, ROM, and/or the like), internal storage 1520 (e.g., magnetic, optical, solid-state storage, and/or organic), and/or IO interface 1525, any of which can be coupled on a communication mechanism or bus 1530 for communicating information or embedded in the computer device 1505. IO interface 1525 is also configured to receive images from cameras or provide images to projectors or displays, depending on the desired implementation.

Computer device 1505 can be communicatively coupled to input/user interface 1535 and output device/interface 1540. Either one or both of the input/user interface 1535 and output device/interface 1540 can be a wired or wireless interface and can be detachable. Input/user interface 1535 may include any device, component, sensor, or interface, physical or virtual, that can be used to provide input (e.g., buttons, touch-screen interface, keyboard, a pointing/cursor control, microphone, camera, braille, motion sensor, accelerometer, optical reader, and/or the like). Output device/interface 1540 may include a display, television, monitor, printer, speaker, braille, or the like. In some example implementations, input/user interface 1535 and output device/interface 1540 can be embedded with or physically coupled to the computer device 1505. In other example implementations, other computer devices may function as or provide the functions of input/user interface 1535 and output device/interface 1540 for a computer device 1505.

Examples of computer device 1505 may include, but are not limited to, highly mobile devices (e.g., smartphones, devices in vehicles and other machines, devices carried by humans and animals, and the like), mobile devices (e.g., tablets, notebooks, laptops, personal computers, portable televisions, radios, and the like), and devices not designed for mobility (e.g., desktop computers, other computers, information kiosks, televisions with one or more processors embedded therein and/or coupled thereto, radios, and the like).

Computer device 1505 can be communicatively coupled (e.g., via IO interface 1525) to external storage 1545 and network 1550 for communicating with any number of networked components, devices, and systems, including one or more computer devices of the same or different configuration. Computer device 1505 or any connected computer device can be functioning as, providing services of, or referred to as a server, client, thin server, general machine, special-purpose machine, or another label.

IO interface 1525 can include but is not limited to, wired and/or wireless interfaces using any communication or IO protocols or standards (e.g., Ethernet, 802.11x, Universal System Bus, WiMAX, modem, a cellular network protocol, and the like) for communicating information to and/or from at least all the connected components, devices, and network in computing environment 1500. Network 1550 can be any network or combination of networks (e.g., the Internet, local area network, wide area network, a telephonic network, a cellular network, satellite network, and the like).

Computer device 1505 can use and/or communicate using computer-usable or computer readable media, including transitory media and non-transitory media. Transitory media include transmission media (e.g., metal cables, fiber optics), signals, carrier waves, and the like. Non-transitory media include magnetic media (e.g., disks and tapes), optical media (e.g., CD ROM, digital video disks, Blu-ray disks), solid-state media (e.g., RAM. ROM, flash memory, solid-state storage), and other non-volatile storage or memory.

Computer device 1505 can be used to implement techniques, methods, applications, processes, or computer-executable instructions in some example computing environments. Computer-executable instructions can be retrieved from transitory media and stored on and retrieved from non-transitory media. The executable instructions can originate from one or more of any programming, scripting, and machine languages (e.g., C, C++, C#, Java, Visual Basic, Python, Perl. JavaScript, and others).

Processor(s) 1510 can execute under any operating system (OS) (not shown), in a native or virtual environment. One or more applications can be deployed that include logic unit 1560, application programming interface (API) unit 1565, input unit 1570, output unit 1575, and inter-unit communication mechanism 1595 for the different units to communicate with each other, with the OS, and with other applications (not shown). The described units and elements can be varied in design, function, configuration, or implementation and are not limited to the descriptions provided. Processor(s) 1510 can be in the form of hardware processors such as central processing units (CPUs) or in a combination of hardware and software units.

In some example implementations, when information or an execution instruction is received by API unit 1565, it may be communicated to one or more other units (e.g., logic unit 1560, input unit 1570, output unit 1575). In some instances, logic unit 1560 may be configured to control the information flow among the units and direct the services provided by API unit 1565, the input unit 1570, the output unit 1575, in some example implementations described above. For example, the flow of one or more processes or implementations may be controlled by logic unit 1560 alone or in conjunction with API unit 1565. The input unit 1570 may be configured to obtain input for the calculations described in the example implementations, and the output unit 1575 may be configured to provide an output based on the calculations described in example implementations.

Processor(s) 1510 can be configured to execute a method or computer instructions which can involve executing an incremental Principal Component Analysis (PCA) modeler to build a PCA model for sensor measurements associated with one or more cooling devices of a location to be monitored: detecting changes at each time step based on a change in a number of principal components or for when a reconstruction error exceeds a threshold; and evaluating and observing changes to generate feedback regarding the one or more cooling devices as illustrated in FIG. 2.

Processor(s) 1510 can be configured to execute the method or instructions as described above, wherein the executing the incremental PCA modeler can involve, for each group identifier, obtaining all new ones of the sensor measurements associated with the each group identifier for the each time step, for the PCA model not being available for the each group identifier creating the PCA model for the group identifier from the new ones of the sensor measurements; and storing the created PCA model with a flag indicative of there not being the change in the number of principal components; and for the PCA model being available for the each group identifier, updating the PCA model based on the new ones of the sensor measurements; determining whether there is an increase in the principal components for the updated PCA model from the PCA model; and storing the updated PCA model with a flag indicating whether there is an increase in the principal components from the determination as illustrated with respect to FIG. 3.

Processor(s) 1510 can be configured to execute the method or instructions as described above, wherein the detecting changes at the each time step can involve, for a flag associated with the PCA model indicative of the change in the number of principal components having an increase, determining whether there is a change date directly continuing or in close proximity from a previous change date; for the determining indicative of the change date directly continuing or in close proximity from the previous change date, updating a change date database entry associated with the PCA model with the new change date and increment the time steps passed since changed for the PCA model; and for the determining indicative of the change date not directly continuing or in close proximity from the previous change date, adding a new change date database entry associated with the PCA model as illustrated at 401, 402, and 406-408 of FIG. 4.

Processor(s) 1510 can be configured to execute the method or instructions as described above, wherein the detecting changes at the each time step can involve, for a flag associated with the PCA model not indicative of the change in the number of principal components as having an increase, calculating a reconstructed value with the PCA model for the each time step; and calculating the reconstruction error from the reconstructed value; and for the reconstruction error exceeding the threshold, determining whether there is a change date directly continuing or in close proximity from a previous change date; for the determining indicative of the change date directly continuing or in close proximity from the previous change date, updating the change date database entry associated with the PCA model with the new change date and increment the number of time steps passed since changed for the PCA model; and for the determining indicative of the change date not directly continuing from the previous change date, adding the new change date database entry associated with the PCA model as illustrated in 401-405 and 406-408 of FIG. 4.

Processor(s) 1510 can be configured to execute the method or instructions as described above, wherein the evaluating and observing the changes to generate the feedback regarding the one or more cooling devices involves, for each of the changes, determining a number of time steps passed since the PCA model changed from a change date database entry; for the number of time steps passed meeting a threshold, determining score metrics based a division of related data from before the change date and after the change date; and generating feedback for the score metrics exceeding a threshold as illustrated in FIGS. 5 to 8.

Depending on the desired implementation, the feedback can involve active recommendations for adjusting the one or more cooling devices as illustrated in FIG. 10 and FIG. 11.

Depending on the desired implementation, the location to be monitored is a data center server room as illustrated in FIG. 12.

Processor(s) 1510 can be configured to execute a method or instructions as described above, and further involve providing a graphical user interface configured to intake input regarding selection of sensors for providing the sensor measurements, the graphical user interface configured to display the feedback and the changes occurring as illustrated in FIG. 11.

Depending on the desired implementation, the graphical user interface can be configured to intake input regarding sampling frequency for the sensor measurements and grouping granularity to produce one or more group identifiers as illustrated in FIG. 11.

Some portions of the detailed description are presented in terms of algorithms and symbolic representations of operations within a computer. These algorithmic descriptions and symbolic representations are the means used by those skilled in the data processing arts to convey the essence of their innovations to others skilled in the art. An algorithm is a series of defined steps leading to a desired end state or result. In example implementations, the steps carried out require physical manipulations of tangible quantities for achieving a tangible result.

Unless specifically stated otherwise, as apparent from the discussion, it is appreciated that throughout the description, discussions utilizing terms such as “processing,” “computing,” “calculating,” “determining,” “displaying,” or the like, can include the actions and processes of a computer system or other information processing device that manipulates and transforms data represented as physical (electronic) quantities within the computer system's registers and memories into other data similarly represented as physical quantities within the computer system's memories or registers or other information storage, transmission or display devices.

Example implementations may also relate to an apparatus for performing the operations herein. This apparatus may be specially constructed for the required purposes, or it may include one or more general-purpose computers selectively activated or reconfigured by one or more computer programs. Such computer programs may be stored in a computer readable medium, such as a computer-readable storage medium or a computer-readable signal medium. A computer-readable storage medium may involve tangible mediums such as, but not limited to optical disks, magnetic disks, read-only memories, random access memories, solid state devices and drives, or any other types of tangible or non-transitory media suitable for storing electronic information. A computer readable signal medium may include mediums such as carrier waves. The algorithms and displays presented herein are not inherently related to any particular computer or other apparatus. Computer programs can involve pure software implementations that involve instructions that perform the operations of the desired implementation.

Various general-purpose systems may be used with programs and modules in accordance with the examples herein, or it may prove convenient to construct a more specialized apparatus to perform desired method steps. In addition, the example implementations are not described with reference to any particular programming language. It will be appreciated that a variety of programming languages may be used to implement the techniques of the example implementations as described herein. The instructions of the programming language(s) may be executed by one or more processing devices, e.g., central processing units (CPUs), processors, or controllers.

As is known in the art, the operations described above can be performed by hardware, software, or some combination of software and hardware. Various aspects of the example implementations may be implemented using circuits and logic devices (hardware), while other aspects may be implemented using instructions stored on a machine-readable medium (software), which if executed by a processor, would cause the processor to perform a method to carry out implementations of the present application. Further, some example implementations of the present application may be performed solely in hardware, whereas other example implementations may be performed solely in software. Moreover, the various functions described can be performed in a single unit or can be spread across a number of components in any number of ways. When performed by software, the methods may be executed by a processor, such as a general-purpose computer, based on instructions stored on a computer-readable medium. If desired, the instructions can be stored on the medium in a compressed and/or encrypted format.

Moreover, other implementations of the present application will be apparent to those skilled in the art from consideration of the specification and practice of the techniques of the present application. Various aspects and/or components of the described example implementations may be used singly or in any combination. It is intended that the specification and example implementations be considered as examples only, with the true scope and spirit of the present application being indicated by the following claims.

What is claimed is:

1. A method, comprising:
executing an incremental Principal Component Analysis (PCA) modeler to build a PCA model for sensor measurements associated with one or more cooling devices of a location to be monitored;
detecting changes at each time step based on a change in a number of principal components or for when a reconstruction error exceeds a threshold; and
evaluating and observing the changes to generate feedback regarding the one or more cooling devices.

2. The method of claim 1, wherein the executing the incremental PCA modeler comprises, for each group identifier:
obtaining all new ones of the sensor measurements associated with the each group identifier for the each time step;
for the PCA model not being available for the each group identifier:
creating the PCA model for the group identifier from the new ones of the sensor measurements;
and storing the created PCA model with a flag indicative of there not being the change in the number of principal components;
for the PCA model being available for the each group identifier:
updating the PCA model based on the new ones of the sensor measurements;
determining whether there is an increase in the principal components for the updated PCA model from the PCA model; and
storing the updated PC model with the flag indicating whether there is the increase in the principal components from the determination.

3. The method of claim 1, wherein the detecting the changes at the each time step comprises:
for a flag associated with the PCA model indicative of the change in the number of principal components having an increase:
determining whether there is a change date directly continuing or in close proximity from a previous change date;
for the determining indicative of the change date directly continuing or in close proximity from the previous change date, updating a change date database entry associated with the PCA model with a new change date and increment the time steps passed since changed for the PCA model; and
for the determining indicative of the change date not directly continuing or in close proximity from the previous change date, adding a new change date database entry associated with the PCA model.

4. The method of claim 3, wherein the detecting the changes at the each time step comprises:
for the flag associated with the PCA model not indicative of the change in the number of principal components as having the increase:
calculating a reconstructed value with the PCA model for the each time step;
calculating the reconstruction error from the reconstructed value;
for the reconstruction error exceeding the threshold:
determining whether there is the change date directly continuing or in close proximity from the previous change date:
for the determining indicative of the change date directly continuing or in close proximity from the previous change date, updating the change date database entry associated with the PCA model with the new change date and increment the number of time steps passed since changed for the PCA model; and
for the determining indicative of the change date not directly continuing from the previous change date, adding the new change date database entry associated with the PCA model.

5. The method of claim 1, wherein the evaluating and observing the changes to generate the feedback regarding the one or more cooling devices comprises:
for each of the changes:
determining a number of time steps passed since the PCA model changed from a change date database entry;
for the number of time steps passed meeting a step threshold:
determining score metrics based a division of related data from before the change date and after the change date; and
generating the feedback for the score metrics exceeding a score threshold.

6. The method of claim 1, wherein the feedback comprises active recommendations for adjusting the one or more cooling devices.

7. The method of claim 1, wherein the location to be monitored is a data center server room.

8. The method of claim 1, further comprising:
providing a graphical user interface configured to intake input regarding selection of sensors for providing the sensor measurements, the graphical user interface configured to display the feedback and the changes occurring.

9. The method of claim 8, wherein the graphical user interface is configured to intake the input regarding sampling frequency for the sensor measurements and grouping granularity to produce one or more group identifiers.

10. A non-transitory computer readable medium, storing instructions for executing a process, the instructions comprising:
executing an incremental Principal Component Analysis (PCA) modeler to build a PCA model for sensor measurements associated with one or more cooling devices of a location to be monitored;
detecting changes at each time step based on a change in a number of principal components or for when a reconstruction error exceeds a threshold; and
evaluating and observing the changes to generate feedback regarding the one or more cooling devices.

11. The non-transitory computer readable medium of claim 10, wherein the executing the incremental PCA modeler comprises, for each group identifier:
obtaining all new ones of the sensor measurements associated with the each group identifier for the each time step;
for the PCA model not being available for the each group identifier:
creating the PCA model for the group identifier from the new ones of the sensor measurements;
and storing the created PCA model with a flag indicative of there not being the change in the number of principal components;
for the PCA model being available for the each group identifier:
updating the PCA model based on the new ones of the sensor measurements;
determining whether there is an increase in the principal components for the updated PCA model from the PCA model; and
storing the updated PC model with the flag indicating whether there is the increase in the principal components from the determination.

12. The non-transitory computer readable medium of claim 10, wherein the detecting the changes at the each time step comprises:
for a flag associated with the PCA model indicative of the change in the number of principal components having an increase:
determining whether there is a change date directly continuing or in close proximity from a previous change date;
for the determining indicative of the change date directly continuing or in close proximity from the previous change date, updating a change date database entry associated with the PCA model with a new change date and increment the time steps passed since changed for the PCA model; and
for the determining indicative of the change date not directly continuing or in close proximity from the previous change date, adding a new change date database entry associated with the PCA model.

13. The non-transitory computer readable medium of claim 12, wherein the detecting the changes at the each time step comprises:
for the flag associated with the PCA model not indicative of the change in the number of principal components as having the increase:
calculating a reconstructed value with the PCA model for the each time step;
calculating the reconstruction error from the reconstructed value;
for the reconstruction error exceeding the threshold:
determining whether there is the change date directly continuing or in close proximity from a previous change date;
for the determining indicative of the change date directly continuing or in close proximity from the previous change date, updating the change date database entry associated with the PCA model with the new change date and increment the number of time steps passed since changed for the PCA model; and
for the determining indicative of the change date not directly continuing from the previous change date, adding the new change date database entry associated with the PCA model.

14. The non-transitory computer readable medium of claim 10, wherein the evaluating and observing the changes to generate the feedback regarding the one or more cooling devices comprises:
for each of the changes:
determining a number of time steps passed since the PCA model changed from a change date database entry;
for the number of time steps passed meeting a step threshold:
determining score metrics based a division of related data from before the change date and after the change date; and
generating the feedback for the score metrics exceeding a score threshold.

15. The non-transitory computer readable medium of claim 10, wherein the feedback comprises active recommendations for adjusting the one or more cooling devices.

16. The non-transitory computer readable medium of claim 10, wherein the location to be monitored is a data center server room.

17. The non-transitory computer readable medium of claim 10, further comprising: providing a graphical user interface configured to intake input regarding selection of sensors for providing the sensor measurements, the graphical user interface configured to display the feedback and the changes occurring.

18. The non-transitory computer readable medium of claim 17, wherein the graphical user interface is configured to intake input regarding sampling frequency for the sensor measurements and grouping granularity to produce one or more group identifiers.

19. An apparatus, comprising:
a processor, configured to:
execute an incremental Principal Component Analysis (PCA) modeler to build a PCA model for sensor measurements associated with one or more cooling devices of a location to be monitored;
detect changes at each time step based on a change in a number of principal components or for when a reconstruction error exceeds a threshold; and
evaluate and observing the changes to generate feedback regarding the one or more cooling devices.
